(19) United States
(12) Patent Application Publication
(10) Pub. No.: US 2007/0007577 A1
(43) Pub. Date: Jan. 11, 2007

(54) Integrated circuit embodying a non-volatile memory cell

(75) Inventors: Abhijit Bandyopadhyay, San Jose, CA (US); Christopher J. Petti, Mountain View, CA (US); Tanmay Kumar, Pleasanton, CA (US)

Correspondence Address: Zilka-Kotab, PC, P.O. BOX 721120, SAN JOSE, CA, 95172-1120, US

(73) Assignee: MATRIX SEMICONDUCTOR, INC.

(21) Appl. No.: 11/175,688

(22) Filed: Jul. 6, 2005

(51) Int. Cl. H01L 29/788

(52) U.S. Cl. 257/315

(57) ABSTRACT

An integrated circuit is provided including at least one memory cell. Such memory cell, in turn, includes a transistor and a capacitor. The transistor includes a source, a drain, and a gate. Further, the capacitor includes a well and a gate. The gate of the transistor remains in communication with the gate of the capacitor. In various other embodiments, the memory cell includes a transistor and a capacitor including wells of differing types (e.g. P-type, N-type). In such embodiments, the well of the transistor abuts the well of the capacitor. In still further embodiments, for a more compact design, a diffusion region of the transistor is situated less than 2.5 μm from a diffusion region of the capacitor.

### BACKGROUND AND FIELD OF THE INVENTION

The present invention relates to memory, and more particularly to non-volatile memory cells.

### SUMMARY

An integrated circuit is provided including at least one memory cell. Such memory cell, in turn, includes a transistor and a capacitor. The transistor includes a source, a drain, and a gate. Further, the capacitor includes a well and a gate. The gate of the transistor remains in communication with the gate of the capacitor.

Yet another integrated circuit is provided again including at least one memory cell. The memory cell includes a transistor with a well of a first type (e.g. N-type, P-type), and a capacitor with a well of a second type (e.g. P-type, N-type). The well of the transistor abuts the well of the capacitor.

Still yet another integrated circuit is provided including at least one memory cell. Such memory cell includes both a transistor and a capacitor each including at least one diffusion region. For a more compact design, the diffusion region of the transistor is situated less than 2.5 μm from the diffusion region of the capacitor.

### BRIEF DESCRIPTION OF THE DRAWINGS

FIG. 1 illustrates a schematic of one exemplary construction of a memory cell, according to one embodiment.

FIG. 2 is an electrical schematic of a memory cell, according to one embodiment.

FIG. 3A is an electrical schematic of a write operation, in accordance with one embodiment.

FIG. 3B is an electrical schematic of an erase operation, in accordance with one embodiment.

FIG. 3C is an electrical schematic of a read operation, in accordance with one embodiment.

FIG. 4A illustrates a layout of memory cells, according to one embodiment.

FIG. 4B illustrates a cross-sectional view of one of the memory cells shown in FIG. 4A taken along line 4B-4B.

FIG. 4C illustrates a cross-sectional view of one of the memory cells shown in FIG. 4A taken along line 4C-4C.

FIG. 5 illustrates another layout of memory cells, according to yet another embodiment.

### DETAILED DESCRIPTION

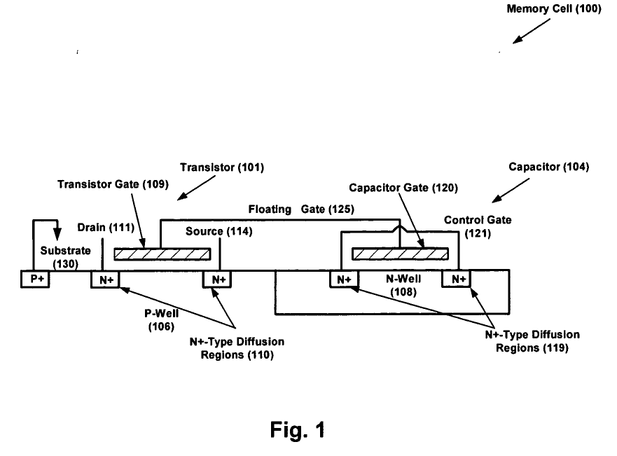

FIG. 1 illustrates a schematic of one exemplary construction of a memory cell 100, according to one embodiment. As shown, an NMOS transistor 101 and a capacitor 104 are formed. To accomplish this, a P-well 106 and an N-well 108 are adjacently formed in an underlying layer (e.g. substrate). While an NMOS-type transistor and P/N-well structures are configured as shown in FIG. 1, it should be noted that a PMOS-type transistor may be employed in place of the NMOS-type transistor, and other underlying structures may be used in other embodiments.

While the substrate may, in one embodiment, be formed from a silicon material (e.g. monocrystalline silicon), it should be noted that any other types of semiconductor material (e.g. SiₓGe_{y} alloy, Ge semiconductor) may also be used, as desired. Further, as an option, a plurality of the memory cells 100 may be formed in a two-dimensional array, and even vertically disposed in the form of a three-dimensional array. In the three-dimensional embodiment, the aforementioned P-well 106 and N-well 108 are not necessarily embodied in the substrate, as shown, but rather above underlying layers of another level of memory cells 100.

The NMOS transistor 101 may be constructed in the P-well 106 utilizing N+-type diffusion regions 110, which are utilized as a source 114 and drain 111 of the NMOS transistor 101. It should be noted that the source 114 and the drain 111 may be formed by diffusion of dopants in the P-well 106. For example, the source 114 and the drain 111 may be formed by updiffusion, outdiffusion, masking and ion implantation, and/or any other desired method capable of producing the N+-type diffusion regions 110.

The NMOS transistor 101 further includes a gate 109 positioned above and between the source 114 and drain 111 of the NMOS transistor 101. While not shown, it should be understood that an insulating layer (e.g. a thin silicon dioxide layer or any other suitable dielectric) may be positioned between the gate 109 and the source 114 and drain 111 (as well as a channel region) of the NMOS transistor 101. In one embodiment, the gate 109 may be constructed from a polysilicon material. Of course, it should be noted that equivalent materials such as metal and/or metal silicide may be used instead of or in combination with the polysilicon material. Finally, the transistor 101 may optionally include a substrate contact 130, as shown.

With continuing reference to FIG. 1, the capacitor 104 may be formed in the N-well 108 by positioning, at least in part, a gate 120 above the N-well 108. While not shown, it should again be understood that an insulating layer (e.g., a thin silicon dioxide layer or any other suitable dielectric, etc.) is positioned between the gate 120 and the N-well 108. Further, while the gate 120 of the capacitor 104 may be constructed utilizing any desired material, one embodiment employs a polysilicon material. Again, polysilicon equivalents (e.g. metal and/or metal silicide) may also be employed.

In order to make electrical contact to the N-well 108, N+-type diffusion regions 119 are formed therein. These N+-type diffusion regions 119 may be placed anywhere within the N-well 108, including adjacent to, partially or wholly under, or completely separated from the gate 120. The N+-type diffusion regions 119 are placed in areas where metallic contacts are made to the N-well 108, but they may also be placed in areas without contacts. Again, the N+-type diffusion regions 119 may be formed by updiffusion, outdiffusion, masking and ion implantation, and/or any other desired method capable of producing the N+-type diffusion regions 119.

Further, in a manner that will soon become apparent, the gate 120 of the capacitor 104 resides in communication with the gate 109 of the NMOS transistor 101. In one embodiment, the gates 109, 120 of the transistor 101 and capacitor 104 may remain in electrical communication. While one example of providing such communication between the gates 109, 120 of the transistor 101 and capacitor 104 is set forth herein, it should be noted that any type of communication is contemplated. Just by way of example, the gates 109, 120 of the transistor 101 and capacitor 104 may have a single, integral piece of polysilicon material or the like (i.e. “single-poly” memory cell 100), or may include multiple separate pieces of such material residing in communication, etc.

In one embodiment, a floating gate 125 is thereby formed which is capable of exhibiting the well known Fowler-Nordheim electron tunneling effect. Further, the N+-type diffusion regions 119 in the N-well 108 of the capacitor 104 may, in one embodiment, operate as a control gate 121 of the memory cell 100. By this structure, the memory cell 100 may take the form of Electrically Erasable Programmable Read-Only Memory (EEPROM) capable of read-write operations, re-writeable operations, etc. Of course, however, the various features set forth herein may be used to construct any desired type of non-volatile memory.

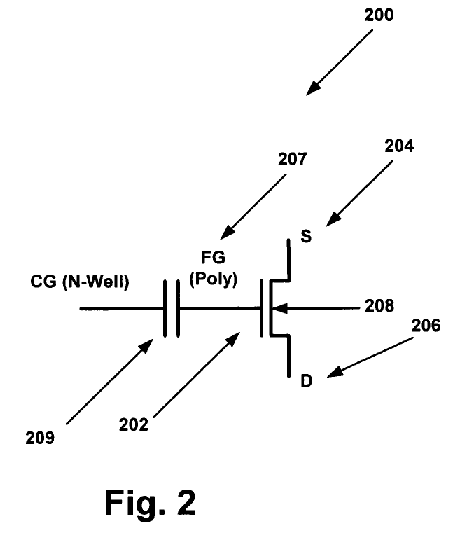

FIG. 2 is an electrical schematic of a memory cell 200, according to one embodiment. As shown, included is an NMOS transistor 202 with a source 204, a drain 206, and a gate 207. A substrate 208 is further shown. Further included is a capacitor 209 including a gate, at least one diffusion region, and an N-well. The gate 207 of the NMOS transistor 202 is in communication with the gate of the capacitor 209, as shown in FIG. 1.

More illustrative information will now be set forth regarding various optional architectures and/or functional features with which the foregoing structure may or may not be implemented, per the desires of the user. It should be strongly noted that the following information is set forth for illustrative purposes and should not be construed as limiting in any manner. Any of the following features may be optionally incorporated with or without the exclusion of other features described.

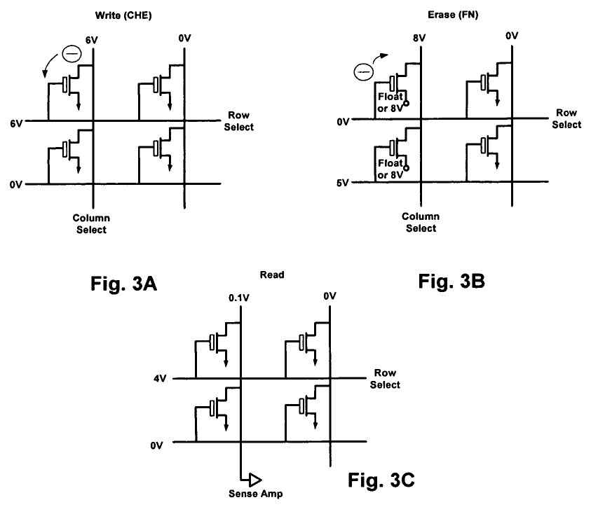

FIGS. 3A, 3B and 3C show electrical schematics illustrating an exemplary operation of memory cells, according to one embodiment. When reviewing the instant figures, it should be understood that each of the four (4) devices shown in each figure may, in one embodiment, take the form of the memory cell 100 shown in FIG. 1.

FIG. 3A is a schematic of a write operation, in accordance with one embodiment. In use, voltages (or lack thereof) are applied to the column selection lines and the row selection lines, as shown, for writing the upper left-hand memory cell while preventing the remaining memory cells from being programmed. It should be noted that the illustrated voltages are merely illustrative and should not be construed as limiting in any manner. In the present embodiment, NMOS Channel Hot Electron (CHE) injection write mechanism may be employed.

Still yet, FIG. 3B is a schematic of an erase operation, in accordance with one embodiment. In use, voltages (or lack thereof) are again applied to the column selection lines and the row selection lines, as shown, for ensuring that the transistor is “floating,” as shown. Again, it should be noted that the illustrated voltages are merely illustrative and should not be construed as limiting in any manner. By this design, the well-known Fowler-Nordheim (FN) tunneling erase mechanism may be employed for driving the electrons from the floating gate. While the CHE and FN mechanisms have been set forth herein, it should be noted that any mechanisms may be employed, as desired.

Finally, FIG. 3C is a schematic of a read operation, in accordance with one embodiment. Table 1 illustrates an exemplary operation which depends on whether the memory cell is written or not. Of course, such table is illustrative in nature and should not be construed as limiting in any way.

TABLE 1

If written, there are charges on the floating gate, and
the cell threshold voltage (V_{T}) will be higher for the
programmed cell which produces no current, driving
the column to ‘1.’
If not written, the cell is un-programmed meaning
that it will conduct, driving the column to ‘0.’

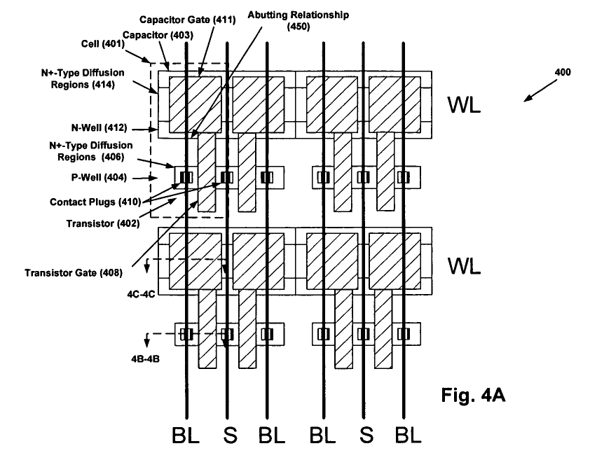

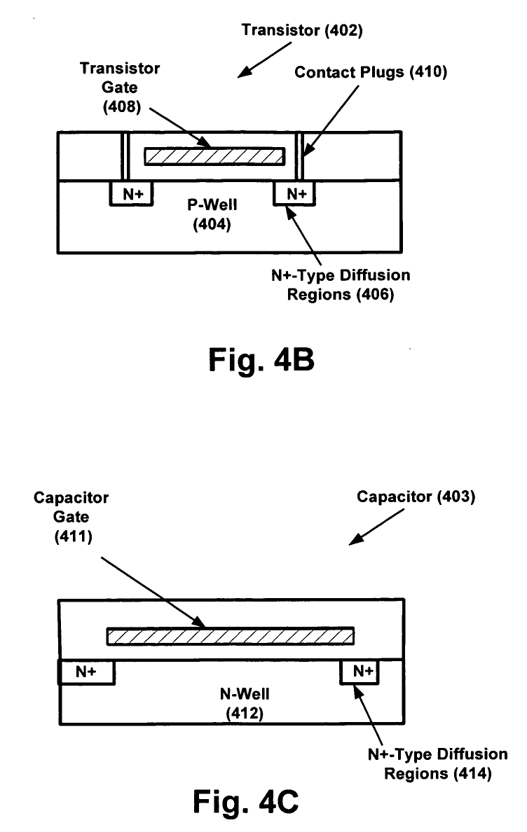

FIG. 4A illustrates a layout 400 of memory cells, according to one embodiment. The following description applies to each of the many memory cells 401 forming the layout 400. As shown, an NMOS transistor 402 and a capacitor 403 are positioned adjacent to each other in the memory cell 401.

The NMOS transistor 402 is constructed in a P-well 404 with a pair of N+-type diffusion regions 406 operating as a source and drain. Such source and drain flank a gate 408 of the NMOS transistor 402. Further, a bit line BL and source line S remain in communication with the drain and source N+-type diffusion regions 406, respectively, by way of respective contact plugs 410. While a source line S is shown in the present embodiment to be shared between at least a subset of the memory cells as a common source line, it should be noted that, in an unillustrated embodiment, each of memory cells in the array may be connected to a separate source line. Of course, in such unillustrated embodiment, a one-bit erase would be enabled with the cost of a larger cell area.

As shown in FIG. 4A, the capacitor 403 is constructed in an N-well 412 equipped with N+-type diffusion regions 414. In use, the N-well 412 may operate as word lines WL. As will soon become apparent, contacts may, in some embodiments, be avoided by using this structure, thus providing for a more compact design.

With continuing reference to FIG. 4A, the gate 408 of the NMOS transistor 402 is in communication with a gate 411 of the capacitor 403, wherein the gate 411 of the capacitor 403, in turn, resides above the N-well 412, between the N+-type diffusion regions 414. As an option, the gate 411 of the capacitor 403 may be enlarged in an area above the N-well 412 (with respect to the gate 408 of the NMOS transistor 402), in the manner shown, for providing better capacitance per unit area.

Again, as mentioned earlier, the gate 408 of the NMOS transistor 402 may remain in communication with the gate 411 of the capacitor 403 in any desired manner. While one example of such communication between the gates 408, 411 of the transistor 402 and capacitor 403 is shown, it should be noted that any type of communication is contemplated. The gates 408, 411, for example, may have a single, integral piece of polysilicon material or the like, may include multiple separate pieces of such material, etc.

As is now apparent, the schematic of FIG. 1 shows the capacitor 403 and transistor 402 in a side-by-side relationship for purposes of clarity from an electrical perspective. As shown in FIG. 4A, however, the capacitor 403 and transistor 402 are not necessarily physically positioned as shown in FIG. 1 (but, of course, may be positioned as such in some embodiments). FIGS. 4B and 4C, on the other hand, help illustrate how the capacitor 403 and transistor 402 are indeed situated, in accordance with the present exemplary embodiment.

Specifically, FIG. 4B illustrates a cross-sectional view of one of the memory cells 401 shown in FIG. 4A taken along line 4B-4B, showing the transistor 402. Further, FIG. 4C illustrates a cross-sectional view of one of the memory cells 401 shown in FIG. 4A taken along line 4C-4C, showing the capacitor 403. To this end, while the schematic of FIG. 1 illustrates the capacitor 403 and transistor 402 in a side-by-side relationship, the capacitor 403 and transistor 402 are indeed positioned in the manner shown. This may be beneficial for arraying the cells.

In use of the embodiment of FIGS. 4A, 4B, and 4C, 2 bits may be erased at a time during an erase operation. Table 2 illustrates an exemplary operation of the present embodiment. Of course, the present table and associated voltage values are illustrative in nature and should not be construed as limiting in any way.

TABLE 2

| | Program | Erase | |
|---|---|---|---|
| | (NCHE) | (FN) | Read |
| selected WL | 6 | 0 | 3.3 |
| unselected WLs | 0 | 6 | 0 |
| selected BL | 9 | 11 | 3.3 |
| selected S | 0 | 11 (or float) | 0 |
| unselected BLs | 0 | 0 | 0 |
| unselected S | 0 | 0 | 0 |

Thus, as shown in FIGS. 4A, 4B, and 4C, the wells 404, 412 of differing types (e.g. N-type, P-type) may abut. Note the abutting relationship 450 in FIG. 4A. In the context of the present description, the term abut refers to any desired type of configuration whereby the well of the first type and the well of the second type, at least in part, share an edge or boundary and/or are touching in some manner. Such feature may optionally provide for a more compact layout. It should be understood that the abutting relationship shown in the figures is merely illustrative in nature and should not be construed as limiting in any manner. Of course, other layouts with abutting wells of differing types (e.g. N-type, P-type) are contemplated.

Still yet, numerous contacts may, in one embodiment, be avoided, at least in part, to afford a more compact layout. Note the N+-type diffusion regions 414 serving as word lines WL in FIG. 4A. Of course, such benefit is simply optional and various embodiments are contemplated whereby such contacts are not avoided.

The foregoing feature may be of particular use in various optional applications. Just by way of example, read-write memory cells (e.g. EEPROM) may be included in an array of memory cells of different types [dynamic random access memory (DRAM), static random access memory (SRAM), etc.]. By virtue of the aforementioned compact layout, EEPROM capabilities may be more effectively integrated with other types of memory on a single chip, thus obviating the need for a separate EEPROM chip, a substantial change in processing, etc. This is of particular benefit with “mostly content-only” applications, where a large amount of read-write memory (>1 Mbit) is not necessarily required. Of course, the present technology may be employed in absolutely any desired context to achieve a wide array of benefits, not necessarily including the foregoing.

As is further now apparent, since use of NMOS/PMOS gate-connected transistor combinations is avoided in one embodiment, one of the N+-type diffusion regions 406 of the transistor 402 may be situated less than 2.5 μm from the closest N+-type diffusion region 414 of the capacitor 403, in the context of a predetermined technology (e.g. 0.15 μm). In another embodiment, one of the N+-type diffusion regions 406 of the transistor 402 may be situated less than 2.0 μm from the closest N+-type diffusion region 414 of the capacitor 403. In still yet another embodiment, one of the N+-type diffusion regions 406 of the transistor 402 may be situated less than 1.5 μm from the closest N+-type diffusion region 414 of the capacitor 403.

One reason for such optional compaction of the memory cell 401 is due to the fact that N+-type diffusion regions 406, 414 of the transistor 402 and capacitor 403 are of the same type (e.g. N+-type). Of course, such benefit is simply optional and various embodiments are contemplated without such feature and associated benefits.

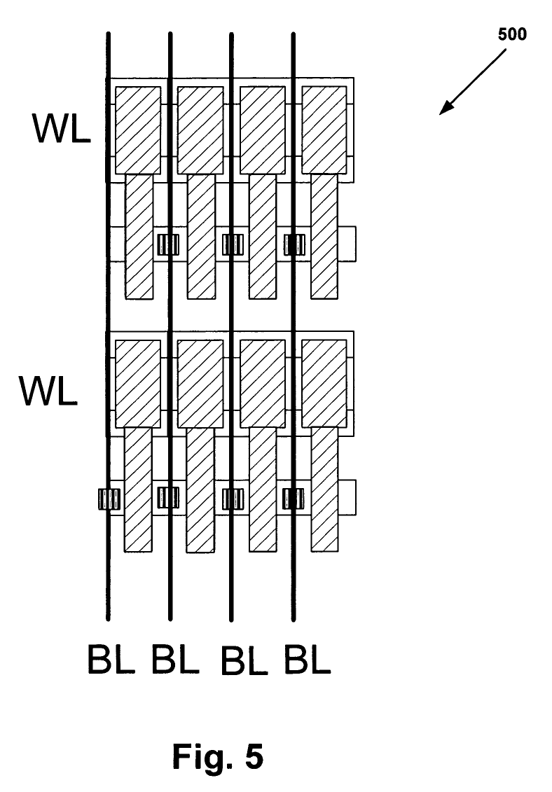

FIG. 5 illustrates another layout 500 of memory cells, according to yet another embodiment. As shown in FIG. 5, the configuration of FIG. 4A is compacted in favor of a virtual ground operation where at least a subset of the memory cells has a virtual ground. As an option, the current embodiment may operate in a manner set forth in A Single Poly-EEPROM Cell Structure for Use in Standard CMOS Processes, K. Ohsaki (IBM Japan Ltd., 800 Ichimiyake, Yasu, Shiga 52023, Japan) et al., IEEE Journal of Solid-State Circuits 29, No. 3, 311-316 (1994), which is incorporated herein by reference in its entirety for all purposes. Further, erasure may involve a row erase mechanism (if tunneling through the N-well capacitor), or a block erase mechanism (if tunneling through the NMOS transistor).

Again, more illustrative information will now be set forth regarding various optional architectures and/or functional features with which the foregoing structure may or may not be implemented, per the desires of the user. It should be strongly noted that the following information is set forth for illustrative purposes and should not be construed as limiting in any manner.

### Additional Embodiments

As an option, various process features and alterations may be employed in the context of the aforementioned NMOS transistor. For example, a high voltage gate oxide may be employed in the order of 15 nm for improving the retention of a memory state during use of the memory cell. Of course, in other embodiments, a thinner gate oxide may be used for the transistor.

Further, a channel length spanning between the aforementioned source and drain of the NMOS transistor may be shortened to the extent possible (e.g. 0.5-0.6 μm) while still providing an acceptable off-current (I_{OFF}).

Still yet, the NMOS transistor may utilize a low threshold voltage for providing more current during use. Further, a native threshold voltage or a low threshold voltage may be employed by blocking or modifying the threshold adjust implant in the transistor channel area, in order to provide more current during use. Still yet, lightly doped drain (LDD) regions may be removed, as set forth in A Logic CMOS Compatible Flash EEPROM for Small Scale Integration, Shalchian and Atarodi, ICM Dec. 9-11, 2003, Cairo, Egypt, 348-351, which is incorporated herein by reference in its entirety for all purposes. While such an alteration may make the memory cell easier to program, such alteration may also reduce the punch-through breakdown of the transistor and/or result in other reliability concerns.

With reference to the operation of the cell, the parasitic leakage of the field NMOS (formed between the NMOS transistor and the N-well) should be suppressed. Though present technology provides adequate immunity in this regard, the field threshold voltage can be further increased by adjusting both P-well and N-well implant conditions.

With respect to the capacitor, a thin gate oxide in the order of 2.6 nm may be used for high coupling if programming with a FN mechanism is desired. Still yet, a thick gate oxide in the order of 15 nm may be used if programming with a CHE mechanism is desired. Of course, a thin gate oxide in the order of 5 nm or 8 nm may be used, in other embodiments. Still yet, in other embodiments, a thicker gate oxide may be used for the capacitor.

Further, the memory cell may have a single metal layer. Still yet, manufacture of the present memory cells may optionally not require added process steps, and use voltages available on chip. For example, the aforementioned memory cell may take the form of a read-write memory cell embodied in a high-density one-time-programmable (OTP) application without additional process steps, as an option. Finally, no additional oxides of different thicknesses, or special design modifications, etc. are necessarily required, in some embodiments.

As mentioned previously, both two and three-dimensional arrays of memory cells are contemplated. In a three-dimensional array embodiment, such array of memory cells has more than one level of the word lines or more than one level of the bit lines. As a further option, the more than one level of bit lines or more than one level of word lines may be monolithically formed above a substrate in a monolithic three-dimensional memory array.

A monolithic three-dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three-dimensional memory arrays.

The foregoing detailed description has described only a few of the many possible implementations of the present invention. For this reason, this detailed description is intended by way of illustration, and not by way of limitations. Variations and modifications of the embodiments disclosed herein may be made based on the description set forth herein, without departing from the scope and spirit of the invention. It is only the following claims, including all equivalents, that are intended to define the scope of this invention. Moreover, the embodiments described above are specifically contemplated to be used alone as well as in various combinations. Accordingly, other embodiments, variations, and improvements not described herein are not necessarily excluded from the scope of the invention.

What is claimed is:

1. An integrated circuit, comprising:
a memory cell including:
a transistor including a source, a drain, and a gate, and
a capacitor including at least one well and a gate;
wherein the gate of the transistor is in communication with the gate of the capacitor.

2. The integrated circuit as recited in claim 1, wherein the transistor includes a substrate.

3. The integrated circuit as recited in claim 1, wherein the transistor is an NMOS transistor.

4. The integrated circuit as recited in claim 1, wherein the gate of the transistor is a floating gate.

5. The integrated circuit as recited in claim 1, wherein at least one diffusion region is formed in the well.

6. The integrated circuit as recited in claim 5, wherein the at least one diffusion region is an N+-type diffusion region, and the well is an N-well.

7. The integrated circuit as recited in claim 5, wherein the at least one diffusion region operates as a control gate of the memory cell.

8. The integrated circuit as recited in claim 1, wherein the capacitor includes a diffusion region formed in the well, and the diffusion region and the well are doped with the same dopant type, where the diffusion region is more heavily doped than the well.

9. The integrated circuit as recited in claim 1, wherein the gate of the capacitor is positioned, at least in part, above the well of the capacitor.

10. The integrated circuit as recited in claim 1, wherein the memory cell is rewritable.

11. The integrated circuit as recited in claim 10, wherein the rewritable memory cell is included in an array of memory cells.

12. The integrated circuit as recited in claim 1, wherein the integrated circuit includes arrays of memory cells of different types.

13. The integrated circuit as recited in claim 1, wherein a plurality of the memory cells is included in an array of memory cells, where each of the memory cells is connected to a separate source line.

14. The integrated circuit as recited in claim 1, wherein a plurality of the memory cells is included in an array of memory cells, where at least a subset of the memory cells share a common source line.

15. The integrated circuit as recited in claim 1, wherein a plurality of the memory cells is included in an array of memory cells, where at least a subset of the memory cells has a virtual ground.

16. The integrated circuit as recited in claim 1, wherein the memory cell has a single metal layer.

17. The integrated circuit as recited in claim 1, wherein the memory cell has a single piece of polysilicon material.

18. The integrated circuit as recited in claim 1, wherein the memory cell is an Electrically Erasable Programmable Read-Only Memory (EEPROM) cell.

19. The integrated circuit as recited in claim 1, wherein a plurality of the memory cells is included in a three-dimensional array having more than one level of the word lines and/or more than one level of the bit lines.

20. The integrated circuit as recited in claim 19, wherein the more than one level of bit lines and/or more than one level of word lines are monolithically formed above a substrate in a monolithic three-dimensional memory array.

21. The integrated circuit as recited in claim 20, wherein the substrate comprises monocrystalline silicon.

22. An integrated circuit, comprising:
a memory cell including:
a transistor including a well of a first type, and
a capacitor including a well of a second type;
wherein the well of the transistor abuts the well of the capacitor.

23. The integrated circuit as recited in claim 22, wherein the well of the first type is a P-well.

24. The integrated circuit as recited in claim 23, wherein the well of the second type is an N-well.

25. An integrated circuit, comprising:
a memory cell including:
a transistor including at least one diffusion region, and
a capacitor including at least one diffusion region;
wherein the diffusion region of the transistor is situated less than 2.5 μm from the diffusion region of the capacitor.

26. The integrated circuit as recited in claim 25, wherein the transistor includes a pair of the diffusion regions defining a source and a drain.

27. The integrated circuit as recited in claim 25, wherein the diffusion region of the transistor is situated less than 2.0 μm from the diffusion region of the capacitor.

28. The integrated circuit as recited in claim 27, wherein the diffusion region of the transistor is situated less than 1.5 μm from the diffusion region of the capacitor.

29. The integrated circuit as recited in claim 25, wherein the memory cell is constructed utilizing 0.15 μm technology.

30. (canceled)
